(19) United States
(12) Patent Application Publication
(10) Pub. No.: US 2006/0246753 A1
(43) Pub. Date: Nov. 2, 2006

(54) Connector

(75) Inventor: Koji Ishikawa, Yokohama (JP)

Correspondence Address: ARENT FOX PLLC, 1050 CONNECTICUT AVENUE, N.W., SUITE 400, WASHINGTON, DC, 20036, US

(73) Assignee: FUJITSU LIMITED

(21) Appl. No.: 11/406,353

(22) Filed: Apr. 19, 2006

(30) Foreign Application Priority Data
Apr. 28, 2005 (JP) 2005-131252

(51) Int. Cl. H05K 1/00

(52) U.S. Cl. 439/79

(57) ABSTRACT

A connector that reduces generation of faults, such as short-circuits of terminals and circuits, by reducing generations of whiskers resulting from use of lead-free solder. The connector comprises a contact part and a housing part. A recess is formed in the area where the contact part is received into the housing part. The recess encloses whiskers generated in the connector at this location. The recess is sized such that whiskers of an anticipated size do not extend from the contact part to the housing part and such that foreign bodies are unlikely to be able to enter the recess.

### CROSS REFERENCE TO RELATED APPLICATION

This application claims priority to Japanese Patent Appln. No. 2005-131252 filed Apr. 28, 2005, the entirety of which is hereby incorporated by reference.

### BACKGROUND OF THE INVENTION

1. Field of the Invention

The present invention relates to a connector, and more specifically to a connector that is able to reduce the adverse effects of whiskers generated when making a conductor part.

2. Background of the Technology

FIG. 1 shows a cross-sectional view of a representative connector of the existing art. The connector is formed by inserting a contact 11 into an opening in a housing 12. The diameter of the contact 11 is slightly larger than the diameter of the opening in the housing 12.

Once emplaced, the contact of the connector is solder connected, for example.

In recent years, use of various kinds of hazardous substances has been restricted in order to protect the environment. For example, in Europe, a regulation referred to as Restriction on Hazardous Substances (ROHS) has been issued to restrict the use of a number of particular chemical substances. Among the restricted substances is lead, which is a common substance in solder. As a result, efforts are being made to develop lead-free solder. Among other applications, lead-free solder is needed for connecting the contact parts of connectors to devices.

Various lead-free solders have been developed, including a number of “tin system” solders. These tin system solders typically use tin (Sn) or tin-copper (Sn—Cu) as a solder constituent.

One problem that has arisen in the development of lead-free solders is the need to address the generation of “whiskers” during the soldering process. It is well known that a needle crystal, referred to interchangeably herein as a “whisker”, is often generated in the lead-free solder application process. In the tin system, for example, tin in the solder is typically the source of the crystals forming such whiskers.

Recently, it has been reported that when the whisker grows or when the grown whisker scatters, additional problems, such as the creation of short-circuits between terminals or to ground can result. Scattering of whiskers occurs, for example, when the whisker is displaced during insertion or removal of the connector.

In the connector illustrated in FIG. 1, a stress is applied to the part of the contact 11 to be soldered, plated, or otherwise connected, when the contact is press-fit into the housing 12. Moreover, a stress is also applied to the contact 11 when a connector is attached to or removed from the contact 11. In the case of connector illustrated in FIG. 1, stresses may arise particularly at boundary locations A to D, the points where the contact 11 and edges of the housing 12 meet. Whiskers can easily be generated at these locations.

FIG. 2 is a close up of the portion of the connector of FIG. 1, near boundary location A. As illustrated in FIG. 2, a whisker 13 can be generated with a root at point A, where the contact 11 meets an edge of the housing 12.

Potential serious impacts can result from generation of such whiskers, including lowering of reliability of apparatuses produced that have whiskers. Various measures have been proposed to suppress whisker generation, as described in the various documents listed as References below. However, since at least some whiskers are inevitably generated with the use of lead-free solder, reduction of whisker generation provides only a limited solution to this problem, and it is therefore very difficult or impossible to completely solve the problem of whisker generation in these existing art solutions.

Moreover, in the various measures proposed in the listed prior art documents, additional means are often required over normal soldering or other plating techniques. For example, it may be necessary for a new additional process to be used when manufacturing a component, in order to reduce generation of whiskers, or an improvement may be required for the solder material itself.

FIGS. 3A and 3B present a front elevation and side cross-sectional view, respectively, of a housing of the existing art.

### REFERENCES

JP-A No. 2002-69688

JP-A No. 2002-164106

JP-A No. 2005-56606

http://www.maruwa-ss.co.ip/pb.pdf (as viewed on Apr. 10, 2005)

http://www.jae.co.jp/gihou/pdf28/q_{—}03.pdf (as viewed on Apr. 10, 2005)

http://www.toyohashiplating.co.ip/New%20information%20of%20Pb%20free%Plating%202.htm0 (as viewed on Apr. 10, 2005)

http://tsc.jeita.or.ip/TSC/COM/MS/7_EASM/Japanese/met/data/Pressrelease_Jpn200306.pdf/ (as viewed on Apr. 10, 2005)

### SUMMARY OF THE INVENTION

Embodiements of the present invention provide connectors that are able to reduce or control generation of whiskers, such as whiskers tending to cause short circuits, in the component to which such connectors are attached or in which such connectors are formed.

In order to solve the problems discussed above, as well as others, the present invention includes a connector comprising a contact portion and a housing portion, the housing portion having a formed recess area into which the contact portion is receivable, such as by press fit. Embodiments of the present invention provide that the depth of the recess area is about 0.5 mm and height of the recess area, as measured between the surface of the received contact portion and a wall of the formed recess area, is about 0.1 mm or less.

Moreover, embodiments of the present invention include a connector comprising a housing portion and a contact portion inserted into an opening formed in the housing portion, the opening in the housing portion including a recess formed in such a shape and size that no internal wall of the recess contacts the received contact portion of the connector.

According to embodiments of the present invention, such problems as short circuits due to generation of whiskers may thereby be prevented without any addition or modification to standard solder plating processes or solder plating materials.

For example, according to one embodiment of the present invention, the potentially whisker generating part is contained within the recess part, such that, if a whisker is generated, the recess prevents or reduces likelihood of contact with the whisker, thereby reducing or eliminating the risk of scattering the whisker and thereby causing additional problems, such as short circuits.

Additional advantages and novel features of the invention will be set forth in part in the description that follows, and in part will become more apparent to those skilled in the art upon examination of the following or upon learning by practice of the invention.

### BRIEF DESCRIPTION OF THE FIGURES

In the drawings:

FIG. 1 shows a side cross-sectional view of a connector of the existing art;

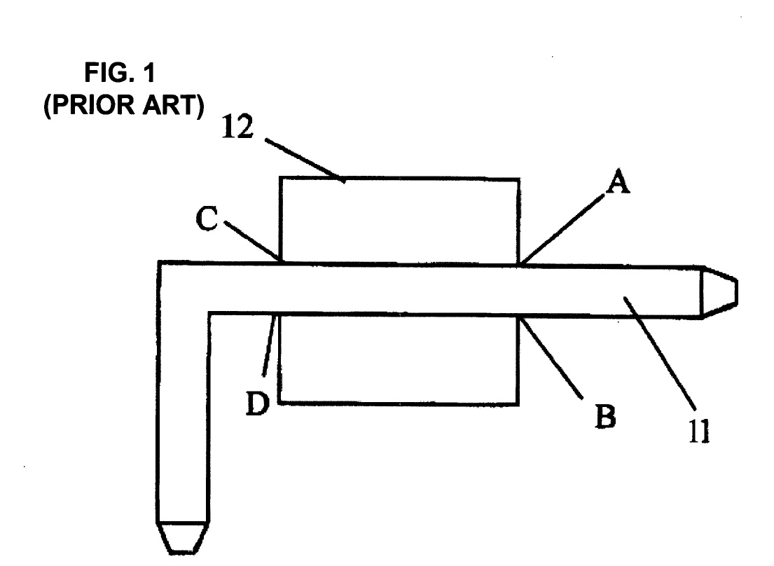

FIG. 2 presents a close-up view of a portion of the connector of FIG. 1;

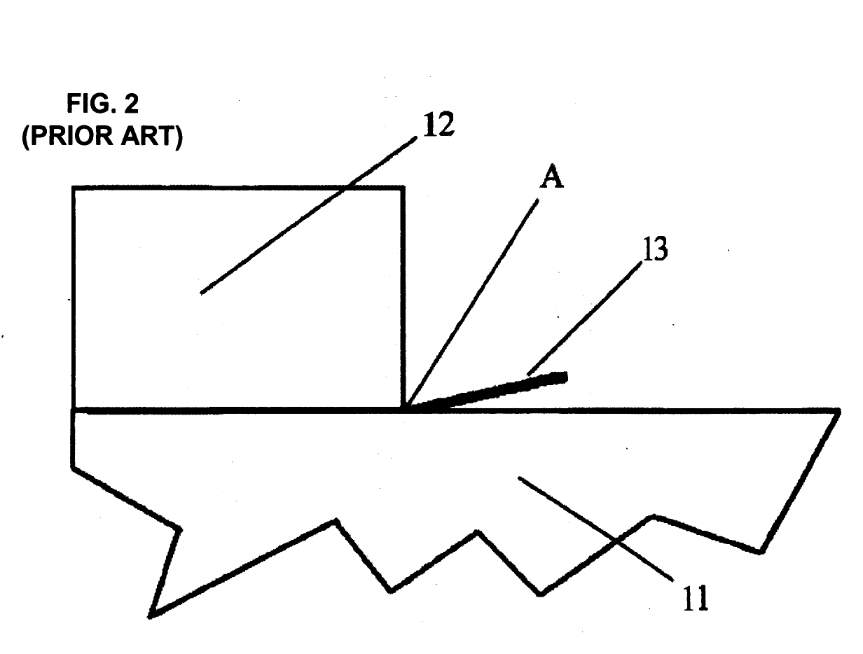

FIGS. 3A and 3B present a front elevation and side cross-sectional view, respectively, of a housing of the existing art;

FIG. 4 is a side cross-sectional view of an exemplary connector in accordance with an embodiment of the present invention;

FIG. 5 presents an enlarged view of the connector of FIG. 3, with a generated whisker shown; and

FIGS. 6A and 6B show a front elevation and side cross-sectional view, respectively, of an exemplary housing in accordance with an embodiment of the present invention.

### DETAILED DESCRIPTION

Exemplary embodiments of the present invention will now be described in accordance with the appended figures.

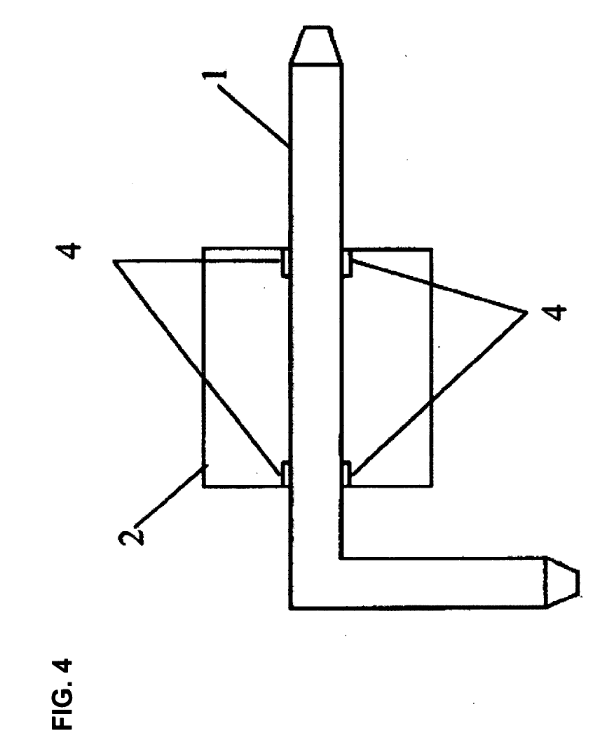

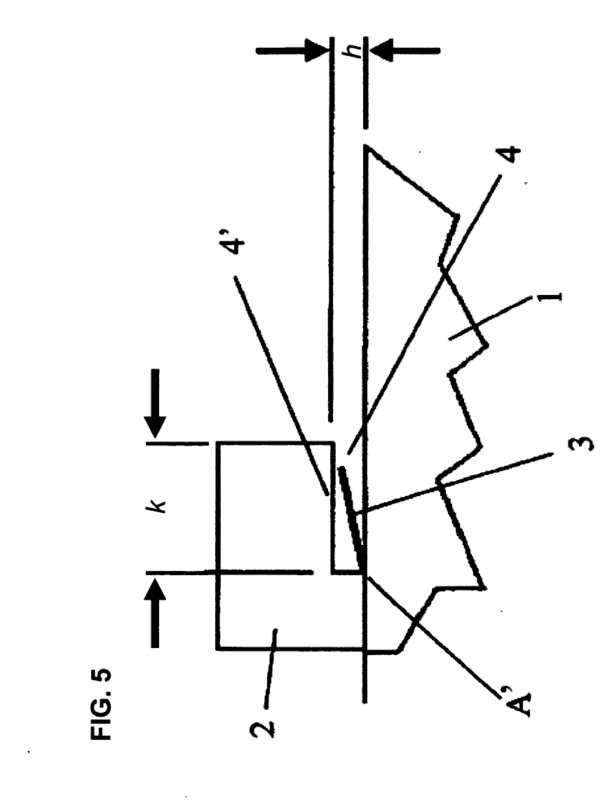

FIG. 4 contains a side elevation of an exemplary connector in accordance with an embodiment of the present invention. FIG. 5 presents close-up of a portion of the connector of FIG. 4, showing a part of the contact portion and the housing portion and a generated whisker.

As shown in the embodiment of FIGS. 4 and 5, recess areas 4 are formed in the opening of the housing portion 2, which receives the contact portion 1, such as by press fit. The recess areas 4 are formed so as to surround completely the received contact 1 and such that the internal wall or walls of the recess areas 4 are separated from the outer surface of the contact portion 1 after insertion into the housing portion 2.

In FIG. 5, a whisker 3 has been generated, such as may occur as a result of stress being applied at point A′. The generated whisker 3 extends from point A′. The recess area 4 formed in the housing portion 2 is of sufficient size so as to prevent the whisker 3 from contacting an internal wall of the recess area 4, even when the whisker 3 generated has grown to the extent shown in FIG. 5.

Since the generated whisker 3 is contained within the recess are 4 formed in the housing portion 2, contact with the whisker 3—even during insertion and removal of the connector—is prevented, thereby minimizing the likelihood of scattering of the whisker 3.

In tests conducted by the applicant using components created in accordance with embodiments of the present invention, it has been shown that whiskers up to the length up to about 400 μm may be generated. In order to prevent contact with such a whisker when the connector is inserted or removed, the depth k of the recess area 4 provided in the housing portion 2 should be sufficient to cover at least a whisker 3 of the test length generated. Accordingly, in one embodiment of the present invention, the depth k of recess portion 4 is set to about 500 μm (=0.5 mm), as illustrated in FIG. 5. This depth k may be varied as required, in accordance with a size of the whisker 3 forecasted, and may be greater or less than 500 μm.

Variation in the size of the recess area 4, in terms of the height h shown in FIG. 5, can also affect possible impacts with a generated whisker 3. For example, in some embodiments, it is preferable that the height h is sufficient to prevent contact by the generated whisker 3 with any internal wall of the recess area 4. In the embodiment shown in FIG. 5, the height h of recess area 4, as measured between the edge of an inserted contact portion 1 and a first wall 4′ of the recess area 4 is set to about 0.05 to 0.1 mm. A problem may arise, for example, when the height h of the recess area 4 is too low, such that the generated whisker 3 contacts the first wall 4′, possibly thereby resulting in scatter of the whisker 3.

On the other hand, if height h of the recess area 4 is too great, foreign matter may easily enters the recess area 4, and such foreign matter may contact the generated whisker 3. When such a possibility is taken into consideration, it is preferable that height h of the recess area 4 be set to about 0.05 mm to 0.1 mm. Such height h can also be altered to other ranges as necessary for the expected size of a whisker generated.

Moreover, it is also possible, in view of containing the area where generation of a whisker is anticipated as likely, to extend sufficiently the length of the pressure-fitting part, for example, in place of forming a recess in the housing, or to insert another member where a recess part not in contact with the contact surface is inserted into the contact.

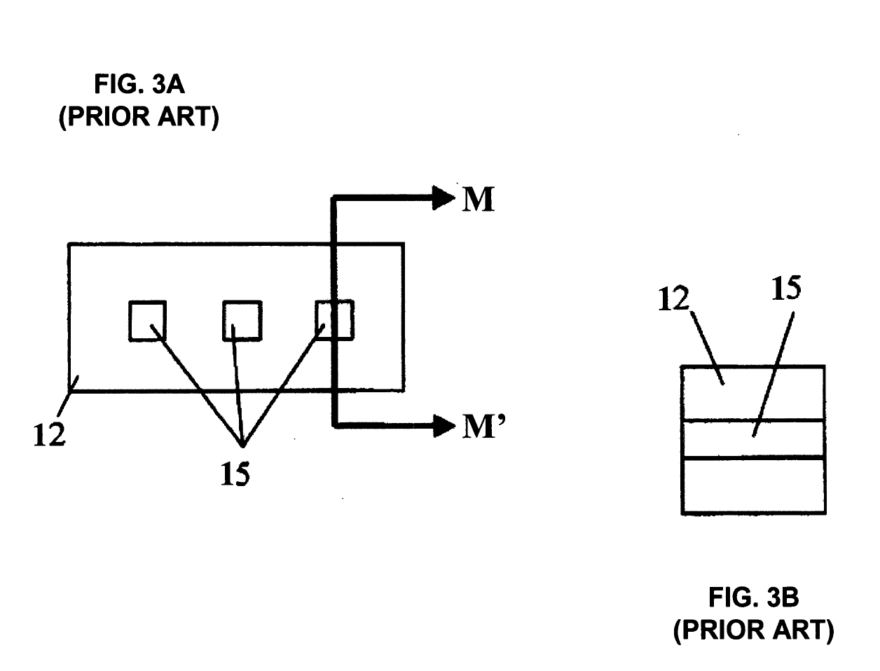

Embodiments of the connector of the present invention will now be compared with an exemplary existing art connector shown in FIGS. 3A and 3B.

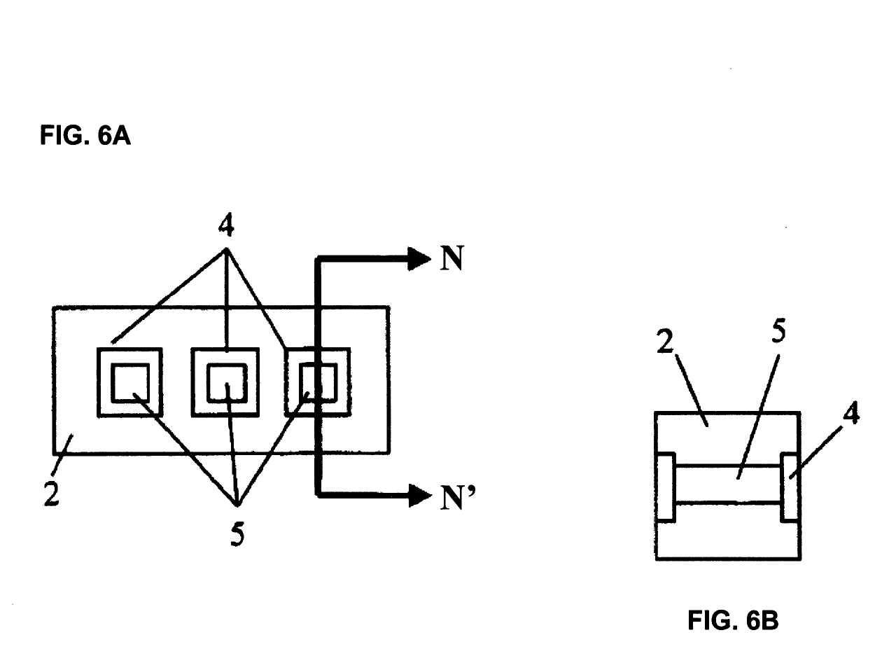

FIGS. 6A and 6B illustrate a front elevation of an exemplary connector housing and a side elevation, respectively, in accordance with an embodiment of the present invention, the side elevation of FIG. 6B being shown along the line N-N′ of FIG. 6A. For comparison purposes, FIGS. 3A and 3B illustrate a front elevation of an exemplary connector housing and a side elevation, respectively, in accordance with a connector of the existing art, the side elevation of FIG. 3B being shown along the line M-M′ of FIG. 3A.

As illustrated in the embodiment of the connector of FIGS. 6A and 6B, the recess areas 4 of the housing portion 2 are formed in the periphery of each opening 5, and contact portions are insertable into each opening 5. Similar recess areas 4 are formed at both ends of the housing portion 2.

In contrast, no recess area is formed in the periphery of the opening 15 in the housing 12 of the existing art illustrated in FIGS. 3A and 3B. Accordingly, unlike the connector housing portion 2 in the embodiment of the present invention shown in FIGS. 6A and 6B, no recess area of housing exists to contain any whiskers generated by the existing art connector, and it is therefore difficult thereby to prevent scattering of generated whiskers.

In the connector illustrated in FIGS. 6A and 6B, the openings 5 and recess areas 4 are formed in a generally rectangular shape, which corresponds to the cross-sectional shape of the contact portion to be inserted thereinto. However, these elements may be formed in various cross-sectional shapes, such as circular or the like.

Example embodiments of the present invention have now been described in accordance with the above advantages. It will be appreciated that these examples are merely illustrative of the invention. Many variations and modifications will be apparent to those skilled in the art.

1. A connector, comprising:
a housing portion, the housing portion including an opening, the opening including a first opening portion for receiving a contact portion and a second opening portion, wherein the second opening portion has a first wall; and
a contact portion receivable into the first opening portion, the contact portion having an external surface;
wherein, upon receiving of the contact portion into the first opening portion, the first wall of the recess area is spaced at least a minimum distance from the external surface of the contact portion.

2. The connector of claim 1, wherein the contact portion is receivable into the first opening portion via a press fit.

3. The connector of claim 1, wherein the second opening portion has a depth, the depth of the second opening portion being about 0.5 mm.

4. The connector of claim 1, wherein the at least a minimum distance is about 0.1 mm or less.

5. The connector of claim 1, wherein the second opening portion is sized such that a whisker of an anticipated size that is formed within the second opening portion is contained within the second opening portion.

6. The connector of claim 1, wherein the second opening portion is sized such that a foreign body of an anticipated size is prevented from entering the second opening portion.

7. The connector of claim 1, wherein, upon insertion into the housing portion, a plating is applied to the connector.

8. The connector of claim 7, wherein the plating comprises a lead-free solder.

9. A connector housing, comprising:
a housing body;
a contact receiving opening formed in the housing body, the contact receiving opening capable of receiving a contact having an outer surface; and
a recess area formed in the housing body, the recess area communicating with the contact opening;
wherein the recess area has a wall portion, and whereupon the contact being received within the contact receiving opening, the wall portion is spaced from the outer surface of the contact.

10. The connector housing of claim 9, wherein the contact is receivable into the contact receiving opening via a press fit.

11. The connector housing of claim 9, wherein the recess area has a depth, the depth of the recess area being about 0.5 mm.

12. The connector housing of claim 9, wherein the wall portion is spaced about 0.1 mm or less from the outer surface of the received contact.

13. The connector housing of claim 9, wherein the recess area is sized such that a whisker of an anticipated size that is formed within the recess area is contained within the recess area.

14. The connector housing of claim 9, wherein the recess area is sized such that a foreign body of an anticipated size is prevented from entering the recess area.

15. A connector, comprising:
a housing, the housing including a first opening for receiving a contact and a second opening circumferentially extending about a first end the first opening, wherein the second opening has at least one wall; and
a contact receivable into the first opening, the contact having an outer surface;
wherein, upon the contact being received into the first opening, the contact extends into the second opening, such that the outer surface of the contact is spaced at least a minimum distance from the at least one wall of the second opening.

16. The connector of claim 15, wherein the contact is receivable into the first opening portion via a press fit.

17. The connector of claim 15, wherein the second opening has a depth, the depth of the second opening being about 0.5 mm.

18. The connector of claim 15, wherein the at least a minimum distance is about 0.1 mm or less.

19. The connector of claim 15, wherein the second opening is sized such that a whisker of an anticipated size that is formed within the second opening is contained within the second opening.

20. The connector of claim 15, wherein the second opening is sized such that a foreign body of an anticipated size is prevented from entering the second opening.
